(19) United States
(12) Patent Application Publication
(10) Pub. No.: US 2017/0357322 A1
(43) Pub. Date: Dec. 14, 2017

(54) TERMINAL DEVICE ON WHICH PIEZO ACTUATOR MODULE USING PIEZO HAS BEEN INSTALLED

(71) Applicant: MPLUS CO., LTD., Suwon-si (KR)

(72) Inventor: Yeon Ho SON, Suwon-si (KR)

(21) Appl. No.: 15/597,271

(22) Filed: May 17, 2017

(30) Foreign Application Priority Data
Jun. 8, 2016 (KR) 10-2016-0071140

(51) Int. Cl. G06F 3/01; G02F 1/1333; B06B 1/06; H01L 41/113; G06F 3/041; H01L 41/09

(52) U.S. Cl. CPC G06F 3/016; G06F 3/041; H01L 41/09; B06B 1/06; H01L 41/1132; G02F 1/1333; G02F 2001/133394

(57) ABSTRACT

A terminal device on which a piezo actuator module using piezo has been installed includes a piezoelectric element subjected to tension or compression when a voltage is applied and configured to generate a voltage when an external force is applied, a mass body connected to the piezoelectric element and configured to control the operating frequency of the piezo actuator module, a vibration plate coupled to the mass body and the piezoelectric element and configured to have a displacement determined by the tension or compression of the piezoelectric element, and a flexible circuit board coupled to one side of the piezoelectric element and configured to transfer a voltage generated by the tension or compression of the piezoelectric element.

### CROSS REFERENCE TO RELATED APPLICATION

The present application claims the benefit of Korean Patent Application No. 10-2016-0071140, filed in the Korean Intellectual Property Office on Jun. 8, 2016, the entire content of which is incorporated herein by reference.

### BACKGROUND OF THE INVENTION

### 1. Technical Field

The present invention relates to a terminal device on which a piezo actuator module using piezo has been installed and, more particularly, to a terminal device on which a piezo actuator module configured to sense a tap on the main body of the piezo actuator module in the state in which a display unit has been deactivated by the piezo actuator of the piezo actuator module, to release the locking state of the terminal device when a pattern of the sensed tap corresponds to a predetermined pattern, and change the display unit from the deactivated state to an activated state.

### 2. Description of Related Art

With the recent development of scientific technology, the function of a portable electronic device, such as a handheld phone, an e-book, a game machine or a PMP, is diversified.

For example, a device field industry of a multimedia player form having a complex function, such as the photographing a photo and a moving image, the playback of music or a moving image file, gaming and the reception of broadcasting content, is being developed.

In order to support and enhance the function of such a portable electronic device, improving a structural part and software part of the multimedia player need to be taken into consideration.

Furthermore, there is an increasing need for a new user interface capable of conveniently controlling the function of the terminal through a simple manipulation even in the state in which a display unit has been deactivated.

Furthermore, in line with the recent needs of a user who wants to conveniently use an electronic device, a device using a touch method of performing input by touching the device is generalized.

The device using the touch method of performing input by touching the device is called a haptic feedback device. Such a method includes a concept that an intuitive experience of the interface user is incorporated and feedback for the touch becomes more plentiful in addition to a concept that information is input by touch the device.

In addition, a vibration motor using piezo has advantages in that a high response speed can be achieved and driving is possible in various frequencies compared to an existing actuator using eccentricity.

Furthermore, such piezo is characterized in that it causes a variation to generate vibration when power is applied and thus sensitively responds to external vibration. Accordingly, such characteristics can be used in various manners.

### PRIOR ART DOCUMENT

### Patent Document

(Patent Document 1) Korean Patent Application No. 2014-0095077

### SUMMARY OF THE INVENTION

An object of the present invention is to provide a terminal device including a piezo actuator configured to release a locking state in which the reception of a control command from a user is limited if a pattern of a sensed tap corresponds to a predetermined pattern, to change a display unit from a deactivated state to an activated state, and to sense a tap on a main body in the state in which the display unit has been deactivated in order to drive the display of predetermined screen information on the display unit.

In accordance with an embodiment of the present invention, there is provided a terminal device including a piezo actuator module, the piezo actuator module including a piezoelectric element subjected to tension or compression when a voltage is applied and configured to generate a voltage when an external force is applied, a mass body connected to the piezoelectric element and configured to control the operating frequency of the piezo actuator module, a vibration plate coupled to the mass body and the piezoelectric element and configured to have a displacement determined by the tension or compression of the piezoelectric element, and a flexible circuit board coupled to one side of the piezoelectric element and configured to transfer a voltage generated by the tension or compression of the piezoelectric element.

Furthermore, at least one rubber mass body is coupled to the end of the mass body, the vibration plate is coupled to the bottom of the mass body, and the flexible circuit board is located between the vibration plate and the piezoelectric element coupled to the bottom of the vibration plate.

The terminal device may further include a casing configured to comprise two or more bent parts and sidewalls downward vertically extended from the bent parts, an upper support rubber attached to the inner top surface of the casing, a lower support rubber attached to one surface of the bottom of the piezoelectric element, and a base located under the casing and coupled to the casing to protect the piezo actuator module.

Additionally, the piezoelectric element may have a single layer type or a multi-layer type.

Furthermore, the mass body may have a neck structure. The mass body may include a central part coupled to the piezoelectric element and the vibration plate and arm units extending from the central part to the respective ends of the arm units on both sides and each having a shape in which a longitudinal cross section becomes smaller.

Furthermore, the rubber mass body may be provided in a rectangle at each of the ends of the mass body on both sides of the mass body.

In addition to the aforementioned contents, the vibration plate may include a cover body of a thin plate shape configured to cover both sides of the mass body and a vibration unit coupled to the center of the bottom of the cover body and extended from the center of the bottom of the cover body to both sides of the cover body.

Furthermore, the vibration plate may include a plurality of square groove parts provided at the center and edges of the vibration unit on the end sides of the vibration unit.

Furthermore, when a voltage is applied to the piezoelectric element, the piezo actuator module generates vibration by moving the vibration unit of the vibration plate up or down by the tension or compression of the piezoelectric element.

Furthermore, when an external force is applied to the piezoelectric element, the piezo actuator module outputs an electric signal generated by the piezoelectric element.

This is described in detail below. If a screen displayed on the external liquid crystals of the terminal device is in a deactivated state, the piezo actuator module may change the screen displayed on the external liquid crystals of the terminal to an activated state in response to the electric signal generated by the piezoelectric element based on the external force applied to the piezoelectric element.

In this case, the external force applied to the piezoelectric element may include a plurality of taps.

The external force applied to the piezoelectric element may include one continued operation including a touch step of making a touch on the terminal device, a drag step of moving an operation along a horizontal axis after the touch operation, and a release step of terminating the touch after the drag step is completed.

Furthermore, the external force applied to the piezoelectric element may be an external force indirectly transferred to the piezoelectric element of the terminal device when the external force is applied to a cover if protection means, such as the cover, has been added to the terminal device.

Furthermore, if power of the terminal device is an OFF state, the piezo actuator module changes power of the terminal to an ON state in response to the electric signal generated by the external force applied to the piezoelectric element.

The external force applied to the piezoelectric element may include a plurality of taps.

In this case, the external force applied to the piezoelectric element may include one continued operation including a touch step of making a touch on the terminal device, a drag step of moving an operation along a horizontal axis after the touch operation, and a release step of terminating the touch after the drag step is completed.

The external force applied to the piezoelectric element may include an external force indirectly transferred to the piezoelectric element of the terminal device when the external force is applied to a cover if protection means, such as the cover, has been added to the terminal device.

### BRIEF DESCRIPTION OF THE DRAWINGS

FIG. 1 is a vertical cross-sectional view of a piezo actuator module according to an embodiment of the present invention.

FIG. 2 is a perspective view showing the enlargement of the elements of the piezo actuator module according to an embodiment of the present invention.

FIG. 3 is a schematic view showing the driving of the vibration plate and the mass body provided in the piezo actuator module according to an embodiment of the present invention.

FIG. 4 is a flowchart illustrating a method of displaying a screen in response to the electric signal of the piezoelectric element according to an embodiment of the present invention.

FIG. 5 is a flowchart showing an external force and a continued operation according to an embodiment of the present invention.

FIG. 6 is a flowchart illustrating a method of turning on power supplied to a terminal in response to the electric signal of the piezoelectric element according to an embodiment of the present invention.

### DETAILED DESCRIPTION

Hereinafter, in this specification, the contents of the present invention will be described in detail in connection with some exemplary embodiments, with reference to the accompanying drawings. It is to be noted that in assigning reference numerals to elements in the drawings, the same reference numerals denote the same elements throughout the drawings even in cases where the elements are shown in different drawings. Furthermore, in describing the embodiments of the present invention, a detailed description of the known functions and constitutions will be omitted if it is deemed to make the gist of the present invention unnecessarily vague.

Furthermore, in describing the elements of this specification, terms, such as the first, the second, A, B, (a), and (b), may be used. However, although the terms are used only to distinguish one element from the other element, the essence, order, or sequence of the elements is not limited by the terms. When it is said that one element is “connected”, “combined”, or “coupled” to the other element, the one element may be directly connected or coupled” to the other element, but it should also be understood that a third element may be “connected”, “combined”, or “coupled” between the two elements.

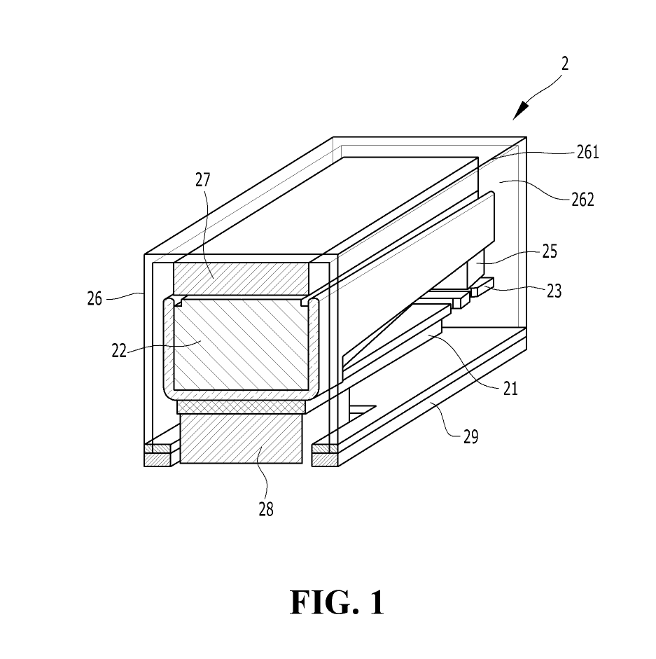

FIG. 1 is a vertical cross-sectional view of a piezo actuator module according to an embodiment of the present invention.

Referring to FIG. 1, in a terminal device including the piezo actuator module 2, the piezo actuator module 2 includes a piezoelectric element 21 subjected to tension or compression when a voltage is applied thereto and configured to generate a voltage when an external force is applied thereto, a mass body 22 connected to the piezoelectric element 21 and configured to control the operating frequency of the piezo actuator module, a vibration plate 23 coupled to the mass body 22 and the piezoelectric element 21 and configured to have its displacement determined by the tension or compression of the piezoelectric element 21, and a flexible circuit board 24 coupled to one side of the piezoelectric element 21 and configured to transfer a voltage generated by the tension or compression of the piezoelectric element 21.

In FIG. 1, the piezoelectric element 21 is coupled to the bottom of the mass body 22 and the vibration plate 23 to generate vibration. Alternatively, the piezoelectric element 21 generates a voltage by tension or compression when an external force is applied thereto and transfers the voltage to the flexible circuit board 24 connected to one side of the piezoelectric element 21.

A driving force can be increased by increasing the number of piezoelectric elements 21 included in the piezo actuator module 2. Accordingly, the entire vibration force of the terminal device can be increased.

Furthermore, the vibration plate 23 and the mass body 22 can be coupled in a neck structure, and thus they can be configured to be horizontal to the piezoelectric element 21. One or more mass bodies 22 may be used by configuring the vibration plate in a vertical direction.

In general, the mass body 22 has a bar shape of a rectilinear form. According to an embodiment of the present invention, however, the mass body 22 may have a shape in which a longitudinal cross section is narrowed toward the end in order to facilitate driving at the end of the vibration plate 23.

The flexible circuit board 24 is a flexible printed circuit board (FPCB) in which electrical circuits are configured. The FPCB means a wiring plate using a flexible insulating board.

More specifically, a single module is formed by sequentially stacking or combining the elements of the piezo actuator module 2 using piezo.

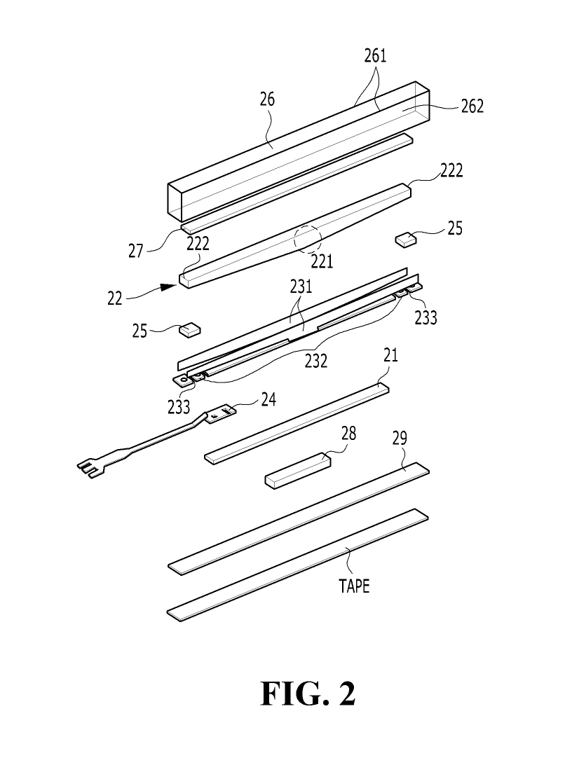

The structure and configuration of the elements of the piezo actuator module 2 using piezo are described in detail below with reference to FIG. 2.

FIG. 2 is a perspective view showing the enlargement of the elements of the piezo actuator module 2 according to an embodiment of the present invention.

Referring to FIG. 2, at least one rubber mass body 25 is coupled to the end of the mass body 22. The vibration plate 23 is coupled to the bottom of the mass body 22. The flexible circuit board 24 is located between the vibration plate 23 and the piezoelectric element 21 coupled to the bottom of the vibration plate 23.

The piezo actuator module 2 may further include a casing 26 configured to comprise two or more bent parts 261 and sidewalls 262 downward and vertically extended from the bent parts 261, an upper support rubber 27 attached to the inner top surface of the casing 26, a lower support rubber 28 attached to one surface of the bottom of the piezoelectric element 21, and a base 29 located under the casing 26 and coupled to the casing 26 to protect the piezo actuator module 2.

Furthermore, the piezoelectric element 21 may have a structure of a single layer type or a multi-layer type structure. As described above, the mass body 22 may have a neck structure, and thus may include a central part 221 coupled to the piezoelectric element 21 and the vibration plate 23 and arm units 222 extended from the central part 221 to the ends on both sides thereof, respectively, and each configured to have a shape in which a longitudinal cross section becomes small.

In addition, the rubber mass body 25 is configured in a rectangle at each of the ends of the mass body 22 on both sides of the mass body 22. The vibration plate 23 includes a cover body 231 configured in a thin plate shape to cover both sides of the mass body 22, a plurality of square groove parts 233 provided at the center and edges of the vibration unit 232 on the end sides of the vibration unit 232, and a vibration unit 232 coupled to the center of the bottom of the cover body 231 and extended from the center of the bottom of the cover body 231 to both sides thereof.

The piezo actuator module 2 may generate vibration by moving the vibration unit 232 of the vibration plate 23 up or down by the tension or compression of the piezoelectric element 21 when a voltage is applied to the piezoelectric element 21, and may output an electric signal through the piezoelectric element 21 when an external force is applied to the piezoelectric element 21.

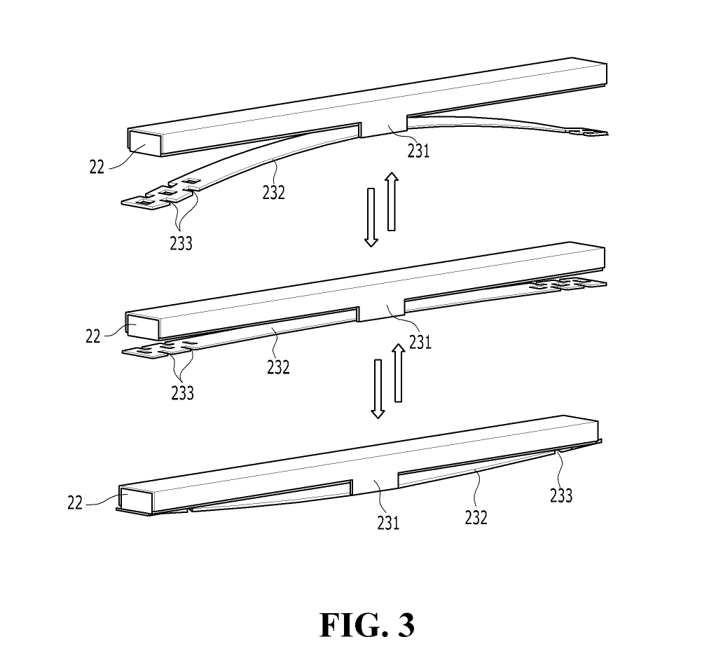

FIG. 3 is a schematic view showing the driving of the vibration plate 23 and mass body 22 of the piezo actuator module 2 according to an embodiment of the present invention.

As described above, the vibration plate 23 and the mass body 22 can be connected in a neck structure, and thus can be configured to be horizontal to the piezoelectric element 21. One or more mass bodies 22 may be used by configuring the vibration plate 23 in a vertical direction.

In general, the mass body 22 has a bar shape of a rectilinear form. According to an embodiment of the present invention, however, the mass body 22 may have a shape in which a longitudinal cross section is narrowed toward the end in order to facilitate driving at the end of the vibration plate 23.

Accordingly, the vibration plate 23 and the piezo actuator module 2 having enhanced movability can be implemented.

This is described in detail. When a voltage is applied to the piezoelectric element 21, the piezoelectric element 21 is subjected to tension or compression. At this time, the vibration plate 23 performs a bending motion up or down as in FIG. 3.

The reason for this is that when a voltage is applied to the piezoelectric element 21, a moment is generated in the vibration plate 23 and a vibration force is generated by the up and down translation motion of the mass body 22.

Furthermore, the mass body 22 can maximize a vibration force because the moment is concentrated on a point at which a displacement is a maximum when the mass body 22 is driven as shown in FIG. 3.

F=mx×xw² (1)

In Equation 1, assuming that mass of the mass body 22 is m, a displacement in a vertical axis is x, and the frequency of the vibration plate 23 is w, the mass of the mass body 22 is increased, but if the driving range of the vibration plate 23 is increased, a vibration force is increased.

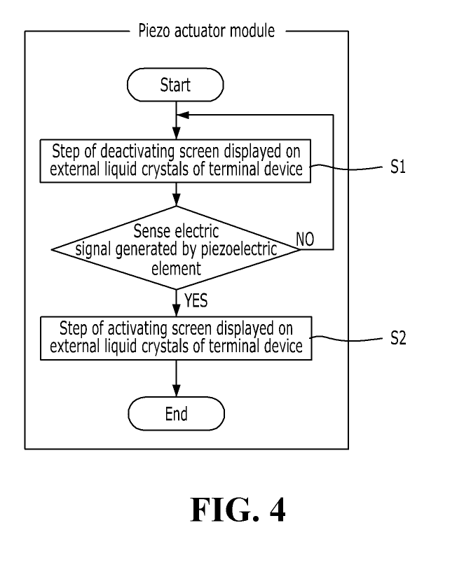

FIG. 4 is a flowchart illustrating a method of displaying a screen in response to the electric signal of the piezoelectric element 21 according to an embodiment of the present invention.

In FIG. 4, when a screen displayed on the external liquid crystals of the terminal device is a deactivated state S1, the piezo actuator module 2 may switch the state of the screen from the deactivate state to an activated state S2 in response to an electric signal output by the piezoelectric element 21 based on an external force applied to the piezoelectric element 21.

The terminal device according to an embodiment of the present invention includes a main body, a display unit disposed at the front of the main body, the piezo actuator module configured to sense a tap on the main body in the state in which the display unit has been deactivated, and a control unit configured to release a locking state in which the reception of a control command from a user is restricted if a pattern of the sensed tap corresponds to a predetermined pattern, to switch the state of the display unit from the deactivated state to the activated state, and to display predetermined screen information on the display unit.

Furthermore, the control unit releases the locking state when a tap pattern corresponding to any one of predetermined tap patterns is applied to the terminal device.

Furthermore, the method according to an embodiment of the present invention includes the steps of sensing a tap on the terminal device in the state in which the display unit has been deactivated, generating, by the piezo actuator module, a signal in response to the sensed tap, determining whether the signal corresponds to a predetermined pattern, and releasing the locking state in which the reception of a control command from a user is restricted if the sensed pattern corresponds to the predetermined pattern, switching the state of the display unit from the deactivated state to the activated state, and displaying predetermined screen information on the display unit.

Furthermore, an external force applied to the piezoelectric element 21 may be indirectly transferred to the piezoelectric element 21 of the terminal device if another protection means, such as a cover, is added to the terminal device.

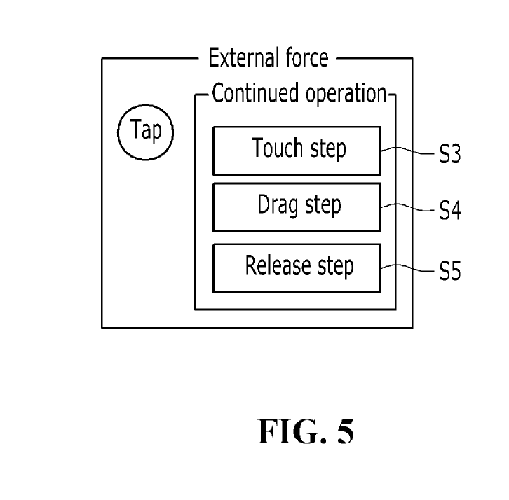

FIG. 5 is a flowchart showing an external force and a continued operation according to an embodiment of the present invention.

More specifically, an external force applied to the piezoelectric element 21 may be one continued operation, including a touch step S3 which may include a plurality of taps and makes a touch on the terminal device, a drag step S4 which moves an operation along a horizontal axis after the touch operation, and a release step S5 which terminates the touch after the drag step S4 is completed.

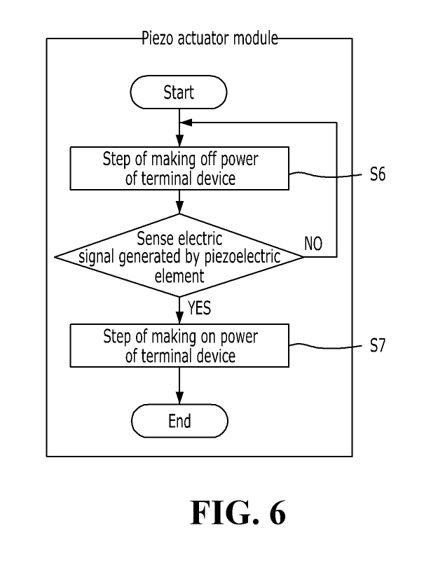

FIG. 6 is a flowchart illustrating a method of turning on power supplied to a terminal in response to the electric signal of the piezoelectric element 21 according to an embodiment of the present invention.

If power of the terminal device is an OFF state S6, the piezo actuator module 2 may change the power of the terminal device to an ON state S7 in response to an electric signal output by an external force applied to the piezoelectric element 21.

Furthermore, the external force applied to the piezoelectric element 21 may be one continued operation, including the touch step S3 of making a touch on the terminal device, the drag step S4 of moving an operation along the horizontal axis after the touch operation, and the release step S5 of terminating the touch after the drag step S4 is completed. If another protection means, such as a cover, has been added to the terminal device, an external force applied to the cover may be indirectly transferred to the piezoelectric element 21 provided in the terminal device.

The present invention has advantages in that a high response speed can be achieved and driving is possible in various frequencies compared to an existing actuator using eccentricity because the vibration motor using piezo is adopted.

Furthermore, such piezo is characterized in that it causes a variation to generate vibration when power is applied and thus sensitively responds to external vibration. Accordingly, if a pattern of a sensed tap corresponds to a predetermined pattern using such characteristics, a locking state in which the reception of a control command from a user is restricted can be released, the display unit can switch from the deactivated state to the activated state, and predetermined screen information can be displayed on the display unit.

Although the present invention has been described above, a person having ordinary skill in the art to which the present invention pertains will recognize that the present invention may be implemented in other forms while maintaining the technical spirit and essential characteristics of the present invention.

Accordingly, the aforementioned embodiments are merely illustrative and are not intended to restrict the scope of the present invention to the aforementioned embodiments only. Furthermore, the illustrated flowcharts are only sequences illustrated to obtain the most preferred results in implementing the present invention, and other steps may be added to the flowcharts or some steps may be omitted from the flowcharts.

The scope of the present invention will be defined by the claims, but it is to be construed that all of changes or modified forms derived from an element directly derived from the writing of the claims and an equivalent element thereof belong to the scope of right of the present invention.

What is claimed is:

1. A terminal device comprising a piezo actuator module, the piezo actuator module comprising:
a piezoelectric element (21) subjected to tension or compression when a voltage is applied and configured to generate a voltage when an external force is applied;
a mass body (22) connected to the piezoelectric element (21) and configured to control an operating frequency of the piezo actuator module;
a vibration plate (23) coupled to the mass body (22) and the piezoelectric element (21) and configured to have a displacement determined by the tension or compression of the piezoelectric element (21); and
a flexible circuit board (24) coupled to one side of the piezoelectric element (21) and configured to transfer a voltage generated by the tension or compression of the piezoelectric element (21).

2. The terminal device of claim 1, wherein:
at least one rubber mass body (25) is coupled to an end of the mass body (22),
the vibration plate (23) is coupled to a bottom of the mass body (22), and
the flexible circuit board (24) is located between the vibration plate (23) and the piezoelectric element (21) coupled to a bottom of the vibration plate (23).

3. The terminal device of claim 2, further comprising:
a casing (26) configured to comprise two or more bent parts (261) and sidewalls (262) downward vertically extended from the bent parts (261);
an upper support rubber (27) attached to an inner top surface of the casing (26);
a lower support rubber (28) attached to one surface of a bottom of the piezoelectric element (21); and
a base (29 located under the casing (26) and coupled to the casing (26) to protect the piezo actuator module (2).

4. The terminal device of claim 1, wherein the piezoelectric element (21) has a single layer type or a multi-layer type.

5. The terminal device of claim 1, wherein:
the mass body (22) has a neck structure, and
the mass body (22) comprises a central part (221) coupled to the piezoelectric element (21) and the vibration plate (23) and arm units (222) extending from the central part (221) to respective ends of the arm units on both sides and each having a shape in which a longitudinal cross section becomes smaller.

6. The terminal device of claim 2, wherein the rubber mass body (25) has a rectangle and is located at each of the ends of the mass body (22) on both sides of the mass body (22).

7. The terminal device of claim 1, wherein the vibration plate (23) comprises:
a cover body (231) of a thin plate shape configured to cover both sides of the mass body (22); and
a vibration unit (232) coupled to a center of a bottom of the cover body (231) and extended from the center of the bottom of the cover body (231) to both sides of the cover body (231).

8. The terminal device of claim 7, wherein the vibration plate (23) comprises a plurality of square groove parts (233) provided at a center and edges of the vibration unit (232) on end sides of the vibration unit (232).

9. The terminal device of claim 1, wherein when a voltage is applied to the piezoelectric element (21), the piezo actuator module (2) generates vibration by moving a vibration unit (232) of the vibration plate (23) up or down by tension or compression of the piezoelectric element (21).

10. The terminal device of claim 1, wherein when an external force is applied to the piezoelectric element (21), the piezo actuator module (2) outputs an electric signal generated by the piezoelectric element (21).

11. The terminal device of claim 10, wherein if a screen displayed on external liquid crystals of the terminal device is in a deactivated state S1, the piezo actuator module (2) changes the screen displayed on the external liquid crystals of the terminal to an activated state S2 in response to the electric signal generated by the piezoelectric element (21) based on the external force applied to the piezoelectric element (21).

12. The terminal device of claim 11, wherein the external force applied to the piezoelectric element (21) comprises a plurality of taps.

13. The terminal device of claim 11, wherein the external force applied to the piezoelectric element (21) comprises one continued operation comprising:
a touch step S3 of making a touch on the terminal device;
a drag step S4 of moving an operation along a horizontal axis after the touch operation; and
a release step S5 of terminating the touch after the drag step S4 is completed.

14. The terminal device of claim 11, wherein the external force applied to the piezoelectric element (21) comprises an external force indirectly transferred to the piezoelectric element (21) of the terminal device when the external force is applied to a cover if protection means including the cover has been added to the terminal device.

15. The terminal device of claim 10, wherein if power of the terminal device is an OFF state S6, the piezo actuator module (2) changes power of the terminal to an ON state S7 in response to the electric signal generated by the external force applied to the piezoelectric element (21).

16. The terminal device of claim 15, wherein the external force applied to the piezoelectric element (21) comprises a plurality of taps.

17. The terminal device of claim 15, wherein the external force applied to the piezoelectric element (21) comprises one continued operation comprising:
a touch step S3 of making a touch on the terminal device;
a drag step S4 of moving an operation along a horizontal axis after the touch operation; and
a release step S5 of terminating the touch after the drag step S4 is completed.

18. The terminal device of claim 15, wherein the external force applied to the piezoelectric element (21) comprises an external force indirectly transferred to the piezoelectric element (21) of the terminal device when the external force is applied to a cover if protection means including the cover has been added to the terminal device.
